(19) United States
(12) Patent Application Publication
(10) Pub. No.: US 2008/0284932 A1
(43) Pub. Date: Nov. 20, 2008

(54) THIN FILM TRANSISTOR SUBSTRATE AND LIQUID CRYSTAL DISPLAY DEVICE COMPRISING THE SAME

(75) Inventors: Seong-Kweon Heo, Suwon-si (KR); Chun-Gi You, Hwaseong-si (KR)

Correspondence Address: CANTOR COLBURN, LLP, 20 Church Street, 22nd Floor, Hartford, CT, 06103, US

(73) Assignee: SAMSUNG ELECTRONICS CO., LTD., Suwon-si (KR)

(21) Appl. No.: 11/832,950

(22) Filed: Aug. 2, 2007

(30) Foreign Application Priority Data
May 16, 2007 (KR) 1020070047734

(51) Int. Cl. G02F 1/136; H01L 21/28; H01L 29/08

(52) U.S. Cl. 349/43; 257/288; 438/151; 257/E29.273; 257/E21.535

(57) ABSTRACT

A thin film transistor including an insulating plate, a thin film transistor formed on the insulating plate, a first insulating layer formed on the insulating plate having the thin film transistor, a reflecting electrode formed on at least a portion of the first insulating layer, and a transparent electrode formed on at least a portion of the first insulating layer and on at least a portion of the reflecting electrode is disclosed. Up to about 85% of a total area of the transparent electrode overlaps with the reflecting electrode. About 10% to about 85% of the total area of the transparent electrode may overlap with the reflecting electrode. About 10% to about 20% of the total area of the transparent electrode may overlap with the reflecting electrode. About 40% to about 50% of the total area of the transparent electrode may overlap with the reflecting electrode. About 75% to about 85% of the total area of the transparent electrode may overlap with the reflecting electrode. Up to about 75% of a total area of the reflecting electrode overlaps with the transparent electrode. The first insulating layer includes an inorganic layer and an organic layer formed on the inorganic layer. At least a portion of the first insulating layer has an embossed surface.

### CROSS-REFERENCE TO RELATED APPLICATION

This application claims priority to and the benefit of Korean Patent Application No. 10-2007-0047734 filed in the Korean Intellectual Property Office on May 16, 2007, the entire contents of which are incorporated herein by reference.

### FIELD OF THE INVENTION

The invention relates to a thin film transistor substrate and a liquid crystal display device comprising the same.

### DESCRIPTION OF THE RELATED ART

Liquid crystal display devices are one of the most widely used flat panel displays. A liquid crystal display device includes a liquid crystal layer interposed between two substrates that are provided with field-generating electrodes. The liquid crystal display device displays images by applying voltages to the field-generating electrodes to generate an electric field that determines the orientation of the liquid crystal molecules which varies the polarization of incident light. The light having varying polarization is either intercepted by or allowed to pass through a polarizing film, thereby displaying images.

Liquid crystal display devices are categorized as non-emissive displays, i.e., they do not themselves produce any light and accordingly, utilize light from lamps of a separate backlight unit or incident ambient light. Depending on the light sources employed, liquid crystal display devices are classified as a transmissive type or a reflective type. The light source of the transmissive liquid crystal display device is a backlight, and the light source of the reflective liquid crystal display device is external light. The reflective liquid crystal display device is usually employed in small-size or medium-size display devices. A transflective liquid crystal display device, which uses both a backlight and an external light as light sources, is usually applied to small-size or middle-size display devices.

A pixel of the transflective liquid crystal display device includes a transmissive area and a reflective area. Usually, a transparent electrode is formed in the transmissive area, and a transparent electrode and a reflecting electrode are formed in the reflective area.

In the transflective liquid crystal display device, reflectance and image sticking tends to become issues. The image sticking is a phenomenon where a faint outline of a previously displayed image remains visible on the screen when the image is changed. It can occur at variable levels of intensity depending on the specific image makeup, as well as the amount of time the core image elements are allowed to remain unchanged on the screen. The required reflectance and image sticking level vary depending on desired devices. Thus, it is necessary to design new device architecture for each desired device, which could delay the whole manufacturing process.

Thus, a thin film transistor substrate that can be designed in a relatively short time while satisfying the required reflectance and image sticking level is required.

### SUMMARY OF THE INVENTION

A thin film transistor substrate according to an embodiment of the invention includes an insulating plate, a thin film transistor formed on the insulating plate, a first insulating layer formed on the insulating plate having the thin film transistor, a reflecting electrode formed on at least a portion of the first insulating layer, and a transparent electrode formed on at least a portion of the first insulating layer and on at least a portion of the reflecting electrode. Up to about 85% of a total area of the transparent electrode overlaps with the reflecting electrode. When a portion of the reflecting electrode, which may contaminate liquid crystals, is covered by the transparent electrode, image sticking caused by the contaminated liquid crystal in the display device may be reduced. About 10% to about 85% of a total area of the transparent electrode overlaps with the reflecting electrode. About 10% to about 20% of the total area of the transparent electrode may overlap with the reflecting electrode. About 40% to about 50% of the total area of the transparent electrode may overlap with the reflecting electrode. About 75% to about 85% of the total area of the transparent electrode may overlap with the reflecting electrode. About 15% to about 75% of a total area of the reflecting electrode overlaps with the transparent electrode. The first insulating layer includes an inorganic layer and an organic layer formed on the inorganic layer. At least a portion of the first insulating layer has an embossed surface.

A thin film transistor substrate according to another embodiment of the invention includes an insulating plate, a thin film transistor formed on the insulating plate, an insulating layer formed on the insulating plate having the thin film transistor, a reflecting electrode formed on at least a portion of the first insulating layer, and a transparent electrode formed on at least a portion of the first insulating layer and on at least a portion of the reflecting electrode. Up to about 75% of a total area of the reflecting electrode overlaps with the transparent electrode. About 15% to about 75% of a total area of the reflecting electrode overlaps with the transparent electrode. About 15% to about 25% of a total area of the reflecting electrode overlaps with the transparent electrode. About 35% to about 45% of a total area of the reflecting electrode may overlap with the transparent electrode. About 65% to about 75% of a total area of the reflecting electrode may overlap with the transparent electrode.

A liquid crystal display device according to an embodiment of the invention includes a first insulating plate, a thin film transistor formed on the first insulating plate, a first insulating layer formed on the thin film transistor, a reflecting electrode formed on at least a portion of the first insulating layer, a transparent electrode formed on at least a portion of the reflecting electrode, a second insulating plate facing the first insulating plate, a common electrode formed on the second insulating plate, and a liquid crystal layer interposed between the first insulating plate and the second insulating plate. About 15% to about 25% of a total area of the reflecting electrode overlaps with the transparent electrode. About 10% to about 20% of a total area of the transparent electrode overlaps with the reflecting electrode. The liquid crystal display device further includes a color filter formed on the second insulating plate and on a second insulating layer formed on the color filter. The color filter is not formed on a portion of the second insulating layer, and the portion corresponds to an area that the reflecting electrode does not overlap with the transparent electrode.

### BRIEF DESCRIPTION OF THE DRAWINGS

FIG. 1 is a schematic cross-sectional view of a liquid crystal display device according to an embodiment of the invention;

FIG. 2 is a top view of a liquid crystal display device according to an embodiment of the invention;

FIG. 3 and FIG. 4 are sectional views of the liquid crystal display device shown in FIG. 2 taken along line III-III′ and line IV-IV′, respectively;

FIG. 5 is a schematic top view of a pixel electrode according to an embodiment of the invention;

FIG. 6 is a schematic top view of a pixel electrode according to another embodiment of the invention; and

FIG. 7 is a schematic top view of a pixel electrode according to another embodiment of the invention.

### DETAILED DESCRIPTION OF THE EMBODIMENTS

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present.

Now, a liquid crystal display device according to an embodiment of the invention will be described in detail with reference to the accompanying drawings.

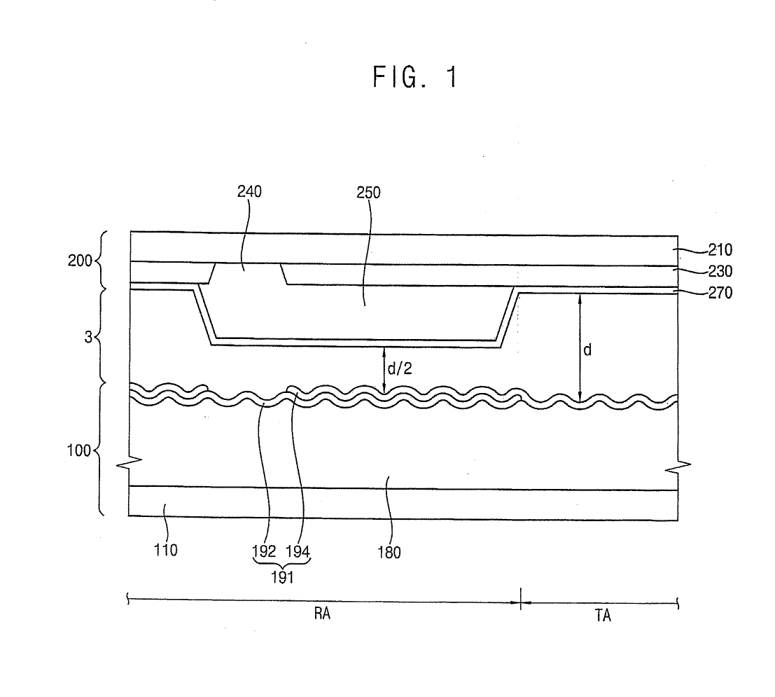

FIG. 1 is a schematic cross-sectional view of a liquid crystal display device according to an embodiment of the invention. As shown in FIG. 1, the liquid crystal display device includes a thin film transistor substrate 100, a common electrode substrate 200 facing the thin film transistor substrate 100, and a liquid crystal layer 3 interposed between the thin film transistor substrate 100 and the common electrode substrate 200.

The thin film transistor substrate 100 includes a first insulating plate 110, a plurality of switching elements (not shown) formed on the first insulating plate 110, a passivation layer 180 formed on the switching elements, and pixel electrodes 191 formed on the passivation layer 180. Each pixel electrode 191 includes a reflecting electrode 192, and a transparent electrode 194 disposed on a portion of reflecting electrode 192 and the passivation layer 180.

The common electrode substrate 200 includes a second insulating plate 210, color filters 230 and a common electrode 270 formed on the second insulating plate 210.

The pixel electrodes 191 that are supplied with data voltages generate electric fields in cooperation with the common electrode 270 that is supplied with a common voltage, which determine the orientations of liquid crystal molecules (not shown) of a liquid crystal layer 3 disposed between the pixel electrode 191 and the common electrode 270 to adjust polarization of the incident light passing through the liquid crystal layer 3.

The liquid crystal display device according to an embodiment of the invention is a transflective type. The transflective liquid crystal display device includes a transmissive area TA and a reflective area RA. In the transmissive areas TA, light from a backlight unit (not shown), which may be disposed under the thin film transistor substrate 100, passes through the liquid crystal layer 3 to display desired images. In the reflective areas RA, external light such as sunlight or ambient light that is incident thereon passes through the common electrode substrate 200 and through the liquid crystal layer 3 to reach the reflecting electrode 194. Then, the external light is reflected by the reflecting electrodes 194 and passes through the liquid crystal layer 3 again, to display desired images.

The color filter 230 has a light hole 240 in the reflective area RA. Usually luminance in the reflective area RA is relatively lower than the transmissive area TA, because external light primarily passes through the transparent electrode and the light reflected on the reflecting electrode secondarily passes through the transparent electrode. The light intensity lessens more when the reflected light passes through a color filter. If a light hole is formed in the color filter, the light directly goes outside without passing through the color filter. Thus, the light hole 240 compensates the shade difference between the reflective area RA and the transmissive area TA. An overcoat layer 250 is formed on the color filters 230. The thickness of the overcoat layer 250 in the reflective area RA is thicker than the thickness in the transmissive area TA.

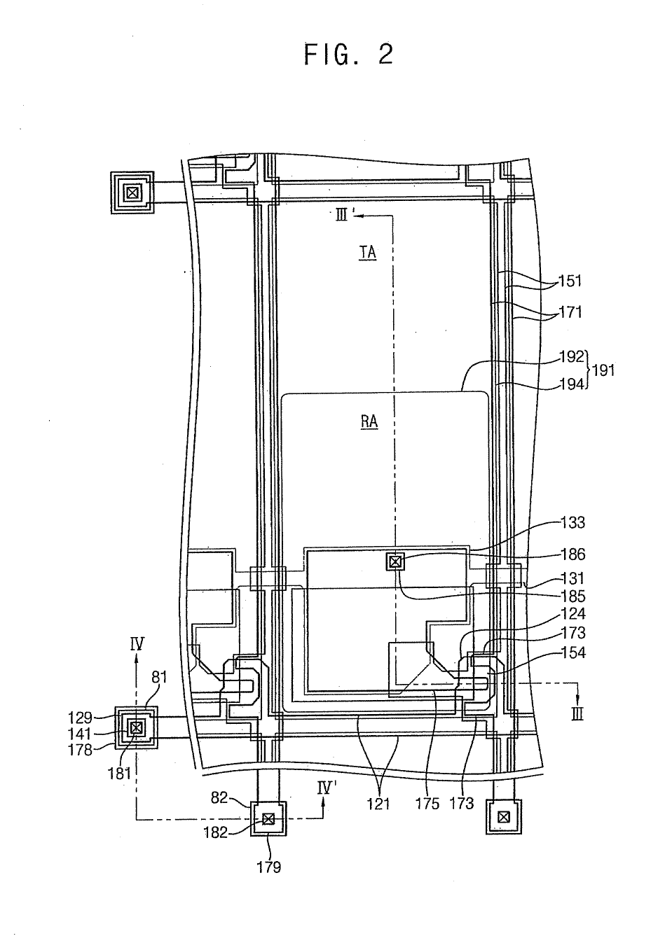

Now, the structure of an embodiment of a liquid crystal display device according to the invention will be described with reference to FIG. 2 to FIG. 4.

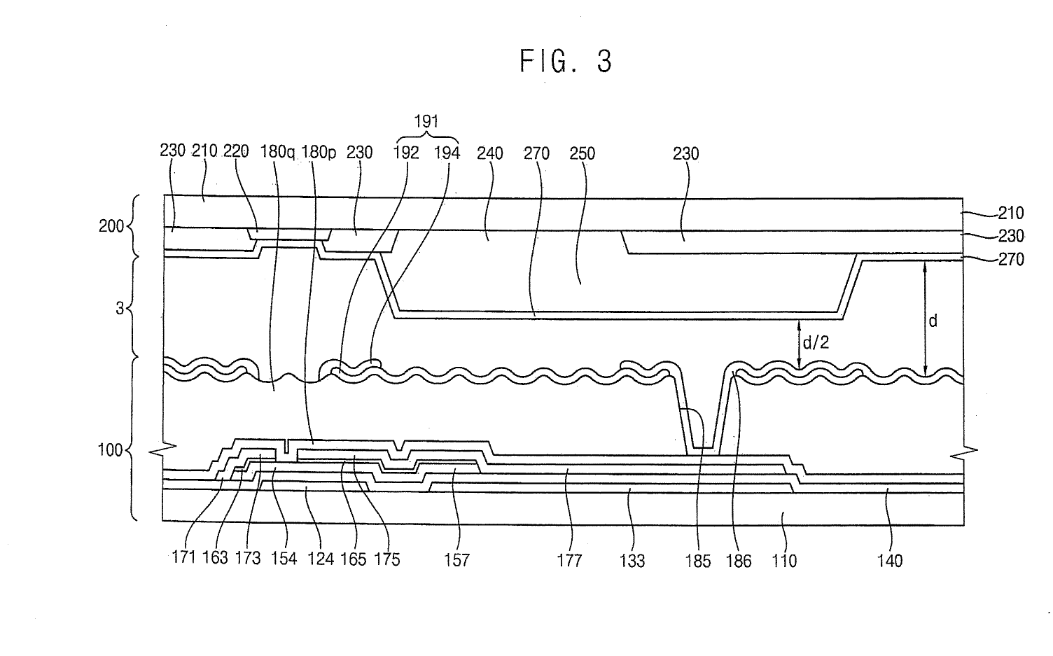

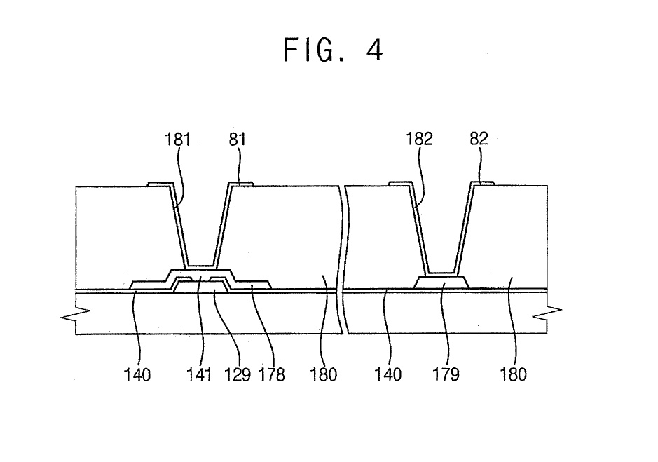

FIG. 2 is a top view of a liquid crystal display device according to an embodiment of the invention. FIG. 3 and FIG. 4 are sectional views of the thin film transistor substrate shown in FIG. 2 taken along line III-III′ and line IV-IV′, respectively.

In FIG. 2, the elements of the thin film transistor substrate 100 are illustrated and the elements of common electrode substrate 200 are omitted for the convenience of explanation.

Referring to FIG. 2, a plurality of gate lines 121 and a plurality of storage electrode lines 131 are formed on a first insulating plate 110. In one embodiment, the first insulating plate 110 includes a material such as transparent glass or plastic.

The gate lines 121 transmit gate signals and extend substantially in a horizontal direction. Each of the gate lines 121 includes a plurality of gate electrodes 124 projecting upward therefrom and a gate pad portion 129 having a large area for contact with another layer or an external driving circuit. A gate driving circuit (not shown) for generating the gate signals may be mounted on a flexible printed circuit (“FPC”) film (not shown), which may be attached to the first insulating plate 110, directly mounted on the first insulating plate 110 (see FIG. 3), or integrated on the first insulating plate 110. The gate lines 121 may extend to be connected to a driving circuit that may be integrated on the first insulating plate 110.

The storage electrode lines 131 are supplied with a predetermined voltage and extend substantially parallel to the gate lines 121. Each of the storage electrode lines 131 is disposed between two adjacent gate lines 121 and disposed closer to the lower gate line. Each of the storage electrode lines 131 includes a storage electrode 133 extending upward and downward therefrom. However, the storage electrode lines 131 may have various shapes and arrangements.

In one embodiment, the gate lines 121 and the storage electrode lines 131 includes an Al-containing metal such as Al and an Al alloy, an Ag-containing metal such as Ag and an Ag alloy, a Cu-containing metal such as Cu and a Cu alloy, a Mo-containing metal such as Mo and a Mo alloy, Cr, Ta, or Ti. However, they may have a multi-layered structure including two conductive films (not shown) having different physical characteristics. In one embodiment, one of the two films includes a low resistivity metal including an Al-containing metal, an Ag-containing metal, and a Cu-containing metal for reducing signal delay or voltage drop. In one embodiment, the other film includes a material such as a Mo-containing metal, Cr, Ta, or Ti, which has good physical, chemical, and electrical contact characteristics with other materials such as indium tin oxide or indium zinc oxide. Examples of the combination of the two films include a lower Cr film and an upper Al (alloy) film, and a lower Al (alloy) film and an upper Mo (alloy) film. However, the gate lines 121 and the storage electrode lines 131 may include various metals or conductors.

Referring to FIG. 3, the lateral sides of the gate lines 121 and the storage electrode lines 131 are inclined relative to the surface of the first insulating plate 110. The inclination angles thereof are in a range of from about 30 to 80 degrees.

A gate insulating layer 140 is formed on the gate lines 121 and the storage electrode lines 131. In one embodiment, the gate insulating layer 140 includes silicon nitride (SiNx) or silicon oxide (SiOx).

In one embodiment, a plurality of semiconductor stripes 151 (see FIG. 2) is formed on the gate insulating layer 140. In one embodiment, the semiconductor stripes 151 include hydrogenated amorphous silicon or polysilicon. Each of the semiconductor stripes 151 extends substantially in the longitudinal direction and includes a plurality of projections 154 branched out toward the gate electrodes 124 and a plurality of projections 157 branched out toward the storage electrode 137. The semiconductor stripes 151 become wide near the gate lines 121 and the storage electrode lines 131 such that the semiconductor stripes 151 cover large areas of the gate lines 121 and the storage electrode lines 131.

A plurality of ohmic contact stripes and islands 163 and 165 are formed on the semiconductor stripes 151. In one embodiment, the ohmic contact stripes and islands 163 and 165 include n+ hydrogenated amorphous silicon heavily doped with an n-type impurity such as phosphorous. In another embodiment, the ohmic contact stripes and islands 163 and 165 may include silicide. Each of the ohmic contact stripes 163 includes a plurality of projections, and the projections and the ohmic contact islands 165 are located in pairs on the projections 154 of the semiconductor stripes 151.

The lateral sides of the semiconductor stripes 151 and the ohmic contacts 163 and 165 are inclined relative to the surface of the first insulating plate 110. In one embodiment, the inclination angles thereof are in a range of about 30 to 80 degrees.

A plurality of data lines 171 and a plurality of drain electrodes 175 are formed on the ohmic contacts 163 and 165. At the same time, a plurality of interconnection members 178 is formed on the gate insulating layer 140.

The data lines 171 transmit data signals and extend substantially in the longitudinal direction to intersect the gate lines 121 and the storage electrode lines 131. Each data line 171 includes a plurality of source electrodes 173 projecting toward the gate electrodes 124, and a data pad portion 179 (see FIG. 2) having a large area for contact with another layer or an external driving circuit. A data driving circuit (not shown) for generating the data signals may be mounted on an FPC film (not shown), which may be attached to the first insulating plate 110, directly mounted on the first insulating plate 110, or integrated on the first insulating plate 110. The data lines 171 may extend to be connected to a driving circuit that may be integrated on the first insulating plate 110.

The drain electrodes 175 are separated from the data lines 171 and disposed opposite the source electrodes 173 with respect to gate electrodes 124. Each of the drain electrodes 175 includes a wide end portion and a narrow end portion. The wide end portion overlaps with a storage electrode 137 of the storage electrode line 131, and the narrow end portion is partly enclosed by the source electrode 173.

The gate electrode 124, the source electrode 173, and the drain electrode 175 along with the projection 154 of the semiconductor stripe 151 form a thin film transistor having a channel formed in the projection 154 disposed between the source electrode 173 and the drain electrode 175.

Referring to FIG. 4, the interconnection member 178 contacts the gate pad portion 129 through a first contact hole 141.

Referring to back to FIG. 3, in one embodiment, the data lines 171, the drain electrodes 175 and the interconnection members 178 each includes a refractory metal such as Cr, Mo, Ta, Ti, or alloys thereof. However, the data lines 171, the drain electrodes 175 and the interconnection members 178 each may have a multi-layered structure including a refractory metal film (not shown) and a low resistivity film (not shown). Examples of the multi-layered structure include a double-layered structure including a lower Cr/Mo (alloy) film and an upper Al (alloy) film, and a triple-layered structure of a lower Mo (alloy) film, an intermediate Al (alloy) film, and an upper Mo (alloy) film. However, the data lines 171 and the drain electrodes 175 may include various metals or conductors.

The data lines 171, the drain electrodes 175 and the interconnection members 178 have inclined edge profiles, and the inclination angles thereof are in a range of from about 30 to 80 degrees.

The ohmic contacts 163 and 165 are interposed only between the underlying semiconductor stripes 151 and the overlying conductors 171 and 175 thereon, and reduce the contact resistance therebetween. Although the semiconductor stripes 151 are narrower than the data lines 171 at most places, the width of the semiconductor stripes 151 becomes larger near the gate lines 121 and the storage electrode lines 131 to smooth the profile of the surface, thereby preventing disconnection of the data lines 171. The semiconductor stripes 151 include some exposed portions that are not covered with the data lines 171 and the drain electrodes 175 such as portions located between the source electrodes 173 and the drain electrodes 175.

A passivation layer 180 is formed on the data lines 171, the drain electrodes 175, the interconnection member 178 and the exposed portions of the semiconductor stripes 151. The passivation layer 180 includes a lower passivation film 180p and an upper passivation film 180q. In one embodiment, the lower passivation film 180p includes an inorganic insulator such as silicon nitride or silicon oxide. In one embodiment, the upper passivation film 180q includes an organic insulator. In one embodiment, the upper passivation film 180q may have a dielectric constant of less than about 4.0, and photosensitivity. At least a portion of the upper passivation film 180q may have an embossed surface. In another embodiment, the passivation layer 180 may have a single-layer structure such as an inorganic or organic insulator.

The passivation layer 180 has a plurality of second and third contact holes 182 and 185 exposing the data pad portions 179 of the data lines 171 and the drain electrodes 175, respectively. The passivation layer 180 has a plurality of fourth contact holes 181 exposing the interconnection members 178 in the gate pad portions 129 of the gate lines 121.

A plurality of pixel electrodes 191 and a plurality of contact assistants 81 and 82 are formed on the passivation layer 180.

Each of the pixel electrodes 191 is formed along the embossed surface of the upper passivation film 180q. Each pixel electrode 191 includes a reflecting electrode 192 and a transparent electrode 194 formed on the reflecting electrode 192.

In one embodiment, the reflecting electrode 192 includes at least two layers having an upper layer of aluminum, silver or alloys thereof and a lower layer of molybdenum, chromium, tantalum or titanium. The upper layer has a low resistance and high reflectance and the lower layer has a good contact characteristic with indium tin oxide or indium zinc oxide. The reflecting electrode 192 may also include one layer.

In one embodiment, the transparent electrodes 194 include a transparent conductor such as indium tin oxide or indium zinc oxide. In one embodiment, the transparent electrode 194 is formed using amorphous indium tin oxide. During the process of depositing amorphous indium tin oxide, water vapor is injected in the manufacturing chamber. Thus, amorphous indium tin oxide has relatively higher hydroxide group content than crystalline indium tin oxide. The hydroxide group is positioned near the crystals of indium zinc oxide alloy and reduces a battery effect when indium zinc oxide contacts a reflective material such as aluminum.

The reflecting electrode 192 is formed on at least a portion of the passivation layer 180. The transparent electrode 194 is formed on at least a portion of the passivation layer 180 and on at least a portion of the reflecting electrode 192. Up to about 85% of a total area of the transparent electrode 194 overlaps with the reflecting electrode 192. About 10% to about 85% of the transparent electrode 194 area overlaps with the reflecting electrode 192.

When a portion of the reflecting electrode 192 is not covered by the transparent electrode 194, the exposed portion of the reflecting electrode 192 may contaminate liquid crystals. This results in image sticking in the display device. Thus, the decrease of the overlapping area between the reflecting electrode 192 and the transparent electrode 194 increases image sticking. On the other hand, the increase of the overlapping area between the reflecting electrode 192 and the transparent electrode 194 decreases image sticking.

When the overlapping area between the transparent electrode 194 and the reflecting electrode 192 decreases, reflectance of the display device increases. This is because external light primarily passes through the transparent electrode 194 and the light reflected on the reflecting electrode 192 secondarily passes through the transparent electrode 194. On the other hand, the increase of the overlapping area between the transparent electrode 194 and the reflecting electrode 192 decreases the reflectance of the display device.

By adjusting the area that the transparent electrode 194 overlaps with the reflecting electrode 192, reflectance and image sticking, which have trade-off relationships, can be variously adjusted. In detail, the increase of the overlapping area reduces image sticking and also reduces reflectance. The decrease of the overlapping area increases reflectance and also increases image sticking. Therefore, it is possible to manufacture thin film transistor substrates in accordance with required specifications of liquid crystal displays.

In one embodiment, about 75% to about 85% of the total area of the transparent electrode 194 overlaps with the reflecting electrode 192. Referring to FIG. 3, about 80% of the total area of the transparent electrode 194 overlaps with the reflecting electrode 192. The display device using the transparent electrode 194 and the reflecting electrode 192 may have lower reflectance and less image sticking.

In another embodiment, about 40% to about 50% of the total area of the transparent electrode 194 overlaps with the reflecting electrode 192. For example, about 45% of the total area of the transparent electrode 194 overlaps with the reflecting electrode 192. The display device using the transparent electrode 194 and the reflecting electrode 192 may have improved reflectance and more image sticking.

In another embodiment, about 10% to about 20% of the total area of the transparent electrode 194 overlaps with the reflecting electrode 192. For example, about 15% of the total area of the transparent electrode 194 overlaps with the reflecting electrode 192. The display device using the transparent electrode 194 and the reflecting electrode 192 may have high reflectance and more image sticking.

About 15% to about 75% of the total area of the reflecting electrode 192 overlaps with the transparent electrode 194.

In one embodiment, about 65% to about 75% of the total area of the reflecting electrode 192 overlaps with the transparent electrode 194. Referring to FIG. 3, about 70% of the total area of the reflecting electrode 192 overlaps with the transparent electrode 194.

In another embodiment, about 35% to about 45% of the total area of the reflecting electrode 192 overlaps with the transparent electrode 194. For example, about 40% of the total area of the reflecting electrode 192 overlaps with the transparent electrode 194.

In another embodiment, about 15% to about 25% of the total area of the reflecting electrode 192 overlaps with the transparent electrode 194. For example, about 20% of the total area of the reflecting electrode 192 overlaps with the transparent electrode 194.

Usually, when the transparent electrode 194 is formed on the reflecting electrode 192, the reflectance of the reflecting electrode 192 decreases by the overlapping portion. In this embodiment, about 15% to about 75% of the reflecting electrode 192 overlaps with the transparent electrode 194. External light does not pass through the transparent electrode 194 and is directly reflected where the transparent electrode 194 is not formed on the reflecting electrode 192. Thus, the reflectance of the reflecting electrode 192 increases.

A fifth contact hole 186 that exposes the drain electrode 175 is formed on the reflecting electrode 192. The pixel electrode 191 is physically and electrically connected to the drain electrode 175 through the third contact hole 185 such that the pixel electrode 191 receives data voltages from drain electrodes 175.

The pixel electrode 191 and the drain electrode 175 each overlaps with the storage electrode 133 to form an additional capacitor referred to as a “storage capacitor,” which enhances the voltage storing capacity of the liquid crystal capacitor.

The contact assistants 81 and 82 are connected to the interconnection members 178 and the data pad portions 179 of data lines 171 through the fourth and the second contact holes 181 and 182, respectively. Contact assistants 81 and 82 protect the interconnection members 178 and the data pad portions 179 and enhance the adhesion of the interconnection members 178 and the data pad portions 179 with external devices.

The interconnection member 178 is interposed between the gate pad portion 129 and the contact assistant 81. In one embodiment, the gate pad portion 129 includes aluminum based material and the contact assistant 81 includes indium tin oxide. The interconnection member 178 prevents aluminum erosion caused by indium tin oxide and enhances the contact characteristic between the gate pad portion 129 and the contact assistant 81.

Hereinafter, the common electrode substrate 200 will be described in detail.

A light-blocking member 220 is formed on the second insulating plate 210 including a material such as transparent glass or plastic. The light-blocking member 220 is referred to as a black matrix, and it prevents light leakage. The light blocking member 200 has a plurality of aperture regions facing the pixel electrodes 191.

A plurality of color filters 230 is formed on the second insulating plate 210, and they are placed substantially within the aperture regions enclosed by the light-blocking member 220. The color filters 230 may extend substantially in the longitudinal direction along the pixel electrodes 191. The color filters 230 may extend substantially in the longitudinal direction along the pixel electrodes 191. The color filters 230 may represent one of the primary colors such as red, green, and blue colors.

The color filter 230 has a light hole 240 in the reflective area RA. The light hole 240 compensates the shade difference between the reflective area RA and the transmissive area TA. In one embodiment, the light hole 240 in a green color filter is the largest among the light holes, and the light hole 240 in a blue color filter is the smallest among the light holes.

An overcoat layer 250, including an organic material, is formed on the light-blocking member 220 and the color filters 230 to protect the color filters 230. The overcoat layer 250 may be omitted.

The thickness of the overcoat layer 250 in the reflective area RA is thicker than the thickness in the transmissive area TA. In one embodiment, the overcoat layer 250 is formed only in the reflective area RA. In one embodiment, the cell gap in the transmissive area TA is about twice the cell in the reflective area RA. The light path difference between the reflective area RA and the transmissive area TA can be reduced by the thickness difference of the overcoat layer 250.

The common electrode 270 is formed on the overcoat layer 250 and may include a transparent conductive material such as indium tin oxide or indium zinc oxide.

Alignment layers (not shown) may be coated on inner surfaces of the thin film transistor substrate 100 and on common electrode substrate 200. Polarizers (not shown) may be provided on each outer surface of the thin film transistor substrate 100 and on common electrode substrate 200.

The liquid crystal layer 3 is subjected to vertical alignment or horizontal alignment.

The liquid crystal display device may further include a plurality of elastic spacers (not shown) supporting the thin film transistor substrate 100 and the common electrode substrate 200 to maintain a uniform cell gap.

The thin film transistor substrate 100 and the common electrode substrate 200 of the liquid crystal display device may be sealed by a sealant. The sealant is disposed on the boundary of the common electrode substrate 200.

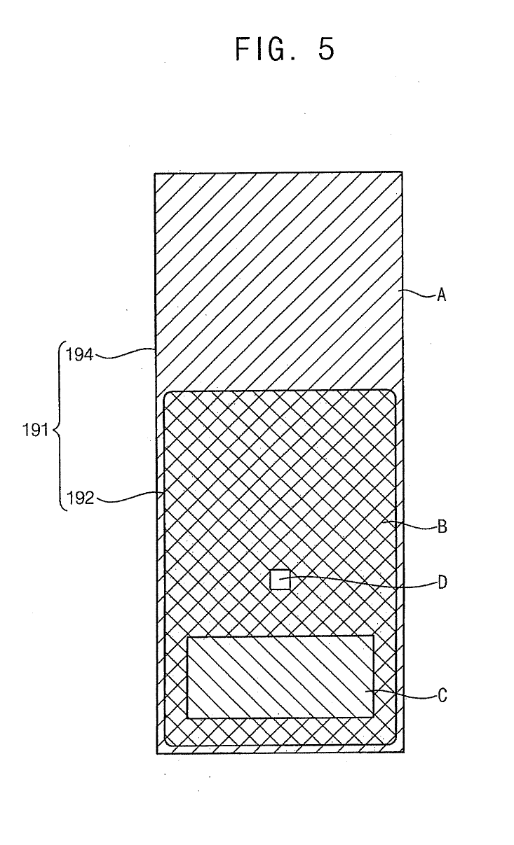

Hereinafter, the pixel electrode 191 according to various embodiments of the invention will be explained in detail with reference to FIGS. 5 to 7.

FIG. 5 is a schematic top view of a pixel electrode according to an embodiment of the invention. Referring to FIG. 5, the pixel electrode 191 includes a reflecting electrode 192 and a transparent electrode 194. The transparent electrode 194 includes area A, area D and area B. In area A, the transparent electrode 194 directly contacts the insulating layer (not shown). In area D, the transparent electrode 194 contacts the drain electrode of the thin film transistor. In area B, the transparent electrode 194 overlaps with the reflecting electrode 192. The reflecting electrode 192 includes area B and area C. In area B, the transparent electrode 194 is formed on the reflecting electrode 192 and in area C, the transparent electrode 194 is not formed on the reflecting electrode 192. The drain electrode of the thin film transistor is connected to the transparent electrode 194 in area D. The reflecting electrode 192 has an opening corresponding to area D. In one embodiment, area C corresponds to about 30% of the total area of the reflective area 192 and area B corresponds to about 70% of the total area of the reflective area 192. In one embodiment, about 80% of the transparent electrode 192 overlaps with the reflecting electrode 194.

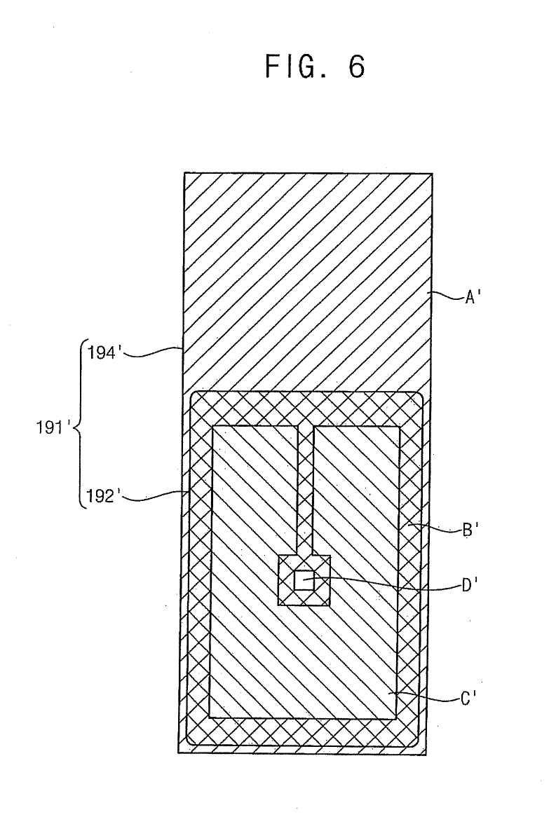

FIG. 6 is a schematic top view of a pixel electrode according to another embodiment of the invention. Referring to FIG. 6, the pixel electrode 191′ includes a reflecting electrode 192′ and a transparent electrode 194′. The transparent electrode 194‘includes area A’, area D′ and area B′. In area A′, the transparent electrode 194′ directly contacts the insulating layer (not shown). In area D′, the transparent electrode 194′ contacts the drain electrode of the thin film transistor. In area B′, the transparent electrode 194′ overlaps with the reflecting electrode 192′. The reflecting electrode 192′ includes area B′ and area C′. In area B′, the transparent electrode 194′ is formed on the reflecting electrode 192′ and in area C′, the transparent electrode 194′ is not formed on the reflecting electrode 192′. The drain electrode of the thin film transistor is connected to the transparent electrode 194′ in area D′. The reflecting electrode 192′ has an opening corresponding to area D′. In one embodiment, area C′ corresponds to about 60% of the total area of the reflective area 192′ and area B′ corresponds to about 40% of the total area of the reflective area 192′. In one embodiment, about 40% of the transparent electrode 192′ overlaps with the reflecting electrode 194′.

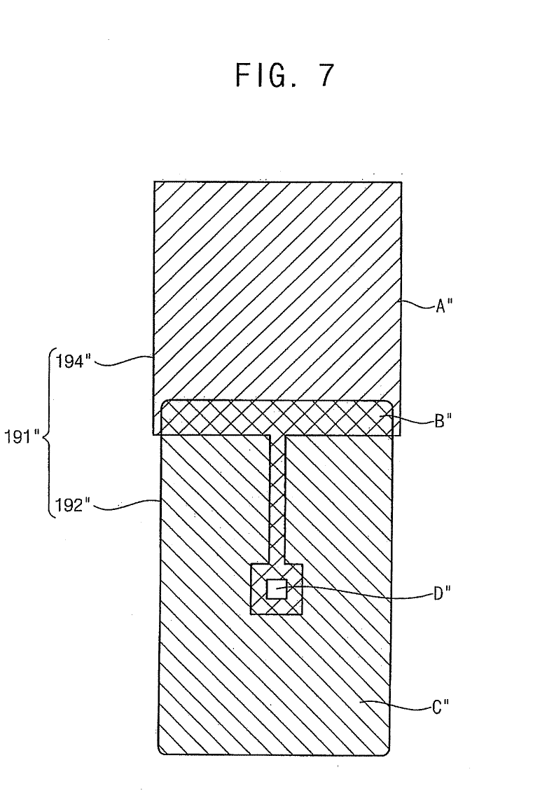

FIG. 7 is a schematic top view of a pixel electrode according to another embodiment of the invention. Referring to FIG. 7, the pixel electrode 191″ includes a reflecting electrode 192″ and a transparent electrode 194″. The transparent electrode 194″ includes area A″, area D″ and area B″. In area A″, the transparent electrode 194″ directly contacts the insulating layer (not shown). In area D″, the transparent electrode 194″ contacts the drain electrode of the thin film transistor. In area B″, the transparent electrode 194″ overlaps with the reflecting electrode 192″. The reflecting electrode 192″ includes area B″ and area C″. In area B″, the transparent electrode 194″ is formed on the reflecting electrode 192″ and in area C″, the transparent electrode 194″ is not formed on the reflecting electrode 192″. The drain electrode of the thin film transistor is connected to the transparent electrode 194″ in area D″. The reflecting electrode 192″ has an opening corresponding to the area D″. In one embodiment, area C″ corresponds to about 60% of the total area of the reflective area 192″ and area B″ corresponds to about 40% of the total area of the reflective area 192″. In one embodiment, about 40% of the transparent electrode 192″ overlaps with the reflecting electrode 194″.

As described above, the pixel electrode may have various structures. The structure of the pixel electrode is not limited to the above described examples. The transparent electrode may overlap with the reflecting electrode in various shapes within an overlapping area of about up to 85%. The reflecting electrode may also overlap with the transparent electrode in various shapes within an overlapping area of about up to 75%.

By adjusting the area that the transparent electrode overlaps with the reflecting electrode, reflectance and image sticking can be variously adjusted. It is possible to manufacture thin film transistor substrates in accordance with required specifications of liquid crystal displays.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A thin film transistor substrate comprising:
an insulating plate;
a thin film transistor formed on the insulating plate;
a first insulating layer formed on the insulating plate having the thin film transistor;
a reflecting electrode formed on at least a portion of the first insulating layer; and
a transparent electrode formed on at least a portion of the first insulating layer and on at least a portion of the reflecting electrode, wherein up to 85% of a total area of the transparent electrode overlaps with the reflecting electrode.

2. The thin film transistor substrate of claim 1, wherein 10% to 20% of the total area of the transparent electrode overlaps with the reflecting electrode.

3. The thin film transistor substrate of claim 1, wherein 40% to 50% of the total area of the transparent electrode overlaps with the reflecting electrode.

4. The thin film transistor substrate of claim 1, wherein 75% to 85% of the total area of the transparent electrode overlaps with the reflecting electrode.

5. The thin film transistor substrate of claim 1, wherein 15% to 75% of a total area of the reflecting electrode overlaps with the transparent electrode.

6. The thin film transistor substrate of claim 1, wherein the first insulating layer comprises an inorganic layer and an organic layer formed on the inorganic layer.

7. The thin film transistor substrate of claim 1, wherein at least a portion of the first insulating layer has an embossed surface.

8. The thin film transistor substrate of claim 1, wherein the thin film transistor comprises:
a gate electrode;
a semiconductor layer;
an ohmic contact layer formed on the semiconductor layer;
a gate insulating layer interposed between the gate electrode and the semiconductor layer; and
a source electrode and a drain electrode each contacting the ohmic contact layer.

9. The thin film transistor substrate of claim 8, wherein at least a portion of the transparent electrode contacts the drain electrode.

10. The thin film transistor substrate of claim 8, wherein the reflecting electrode has a contact hole exposing the drain electrode.

11. The thin film transistor substrate of claim 8, further comprising a gate signal transferring member that transfers a signal to the gate electrode, wherein the gate signal transferring member comprises:
a first conductive layer;
a second insulating layer exposing at least a portion of the first conductive layer;
a second conductive layer formed on the second insulating layer, wherein the second insulating layer contacts the first conductive layer;
a third insulating layer exposing a portion of the second conductive layer; and
a third conductive layer contacting the second conductive layer.

12. A thin film transistor substrate comprising:
an insulating plate;
a thin film transistor formed on the insulating plate;
an insulating layer formed on the insulating plate having the thin film transistor;
a reflecting electrode formed on at least a portion of the first insulating layer; and
a transparent electrode formed on at least a portion of the first insulating layer and on at least a portion of the reflecting electrode, wherein up to 75% of a total area of the reflecting electrode overlaps with the transparent electrode.

13. The thin film transistor substrate of claim 12, wherein 15% to 25% of a total area of the reflecting electrode overlaps with the transparent electrode.

14. The thin film transistor substrate of claim 12, wherein 35% to 45% of a total area of the reflecting electrode overlaps with the transparent electrode.

15. The thin film transistor substrate of claim 12, wherein 65% to 75% of a total area of the reflecting electrode overlaps with the transparent electrode.

16. A liquid crystal display device comprising:
a first insulating plate;
a thin film transistor formed on the first insulating plate;
a first insulating layer formed on the thin film transistor;
a reflecting electrode formed on at least a portion of the first insulating layer;
a transparent electrode formed on at least a portion of the reflecting electrode, wherein 15% to 25% of a total area of the reflecting electrode overlaps with the transparent electrode;
a second insulating plate facing the first insulating plate;
a common electrode formed on the second insulating plate; and
a liquid crystal layer interposed between the first insulating plate and the second insulating plate.

17. The liquid crystal display device of claim 16, wherein 10% to 20% of a total area of the transparent electrode overlaps with the reflecting electrode.

18. The liquid crystal display device of claim 16, further comprising a color filter formed on the second insulating plate and on a second insulating layer formed on the color filter.

19. The liquid crystal display device of claim 18, wherein the color filter is not formed on a portion of the second insulating layer, wherein the portion corresponds to an area that the reflecting electrode does not overlap with the transparent electrode.

20. A method of manufacturing a liquid crystal display device comprising:
forming a thin film transistor formed on the insulating plate;
forming a first insulating layer on the insulating plate having the thin film transistor;
forming a reflecting electrode on at least a portion of the first insulating layer;
forming a transparent electrode formed on at least a portion of the first insulating layer and on at least a portion of the reflecting electrode, wherein up to 85% of a total area of the transparent electrode overlaps with the reflecting electrode;
forming a second insulating plate facing the first insulating plate;
forming a common electrode formed on the second insulating plate; and
forming a liquid crystal layer interposed between the first insulating plate and the second insulating plate.
